(19) United States
(12) Patent Application Publication
(10) Pub. No.: US 2026/0080952 A1
(43) Pub. Date: Mar. 19, 2026

(54) MEMORY SYSTEM AND CONTROL METHOD OF MEMORY SYSTEM

(71) Applicant: Kioxia Corporation, Tokyo (JP)

(72) Inventor: Hiroki KOBAYASHI, Kamakura Kanagawa (JP)

(73) Assignee: Kioxia Corporation, Tokyo (JP)

(21) Appl. No.: 19/065,767

(22) Filed: Feb. 27, 2025

(30) Foreign Application Priority Data
Sep. 19, 2024 (JP) 2024-162505

(51) Int. Cl. G11C 16/30; G11C 16/10; G11C 16/12

(52) U.S. Cl. CPC G11C 16/30; G11C 16/102; G11C 16/12

(57) ABSTRACT

A memory system according to one embodiment includes a memory system includes a memory device, a memory controller, a power supply circuit, and a power storage device. The memory controller controls the memory device. The power supply circuit generates power for driving the memory device and the memory controller based on power supplied from an external power supply, and supplies the generated power to the memory device and the memory controller. The power storage device stores electric energy and to supply the electric energy to the memory device and the memory controller through the power supply circuit in a case where power supply from the external power supply is stopped. The memory controller applies one of first and second write modes having different power consumption to a write operation for the memory device according to a power storage capacity of the power storage device.

### CROSS-REFERENCE TO RELATED APPLICATIONS

This application is based upon and claims the benefit of priority from Japanese Patent Application No. 2024-162505, filed Sep. 19, 2024, the entire contents of which are incorporated herein by reference.

### FIELD

Embodiments described herein relate generally to a memory system and a control method of the memory system.

### BACKGROUND

A NAND flash memory (also referred to as a flash memory) capable of storing data in a nonvolatile manner is known. A memory system including a flash memory is also known. The memory system stores data related to write of data to the flash memory in the volatile memory. In a case where the power supplied to the memory system stops without notice or the voltage value thereof decreases, the data stored in the volatile memory is lost. In order to avoid this, there is a memory system having a power loss protection (PLP) function.

The flash memory includes a plurality of memory cell transistors. It is possible to store multi-valued data in one memory cell transistor. A plurality of write modes for writing multi-valued data in the flash memory has been studied. Each of the plurality of write modes has a different amount of data related to writing of data to the flash memory. Therefore, the amount of data stored in the volatile memory may be different depending on the write mode.

### BRIEF DESCRIPTION OF DRAWINGS

FIG. 1 is a block diagram illustrating an example of a configuration of a memory system according to a first embodiment.

FIG. 2 is a block diagram illustrating an example of a hardware configuration of a memory controller included in the memory system according to the first embodiment.

FIG. 3 is a block diagram illustrating an example of a hardware configuration of a memory device included in the memory system according to the first embodiment.

FIG. 4 is a circuit diagram illustrating an example of a circuit configuration of a memory cell array included in the memory device according to the first embodiment.

FIG. 5 is a schematic diagram illustrating an example of threshold voltage distribution of a memory cell transistor in the memory device according to the first embodiment.

FIG. 6 is a schematic diagram illustrating an example of a write order of a two-stage program in the memory system according to the first embodiment.

FIG. 7 is a schematic diagram illustrating an outline of a write operation using a Foggy-Fine method in the memory system according to the first embodiment.

FIG. 8 is a schematic diagram illustrating an outline of a write operation using an MLC-Fine method in the memory system according to the first embodiment.

FIG. 9 is a block diagram illustrating an example of a functional configuration of the memory controller according to the first embodiment.

FIG. 10 is a graph showing an example of a relationship between a use period of a power storage device and a suppliable energy in the memory system according to the first embodiment.

FIG. 11 is a flowchart illustrating an example of a patrol operation of the memory system according to the first embodiment.

FIG. 12 is a waveform chart showing an example of a method of checking a power storage capacity of the power storage device in the memory system according to the first embodiment.

FIG. 13 is a flowchart illustrating a specific example of the patrol operation of the memory system according to the first embodiment.

FIG. 14 is a flowchart illustrating a specific example of an operation at the time of supplying a logical block of the memory system according to the first embodiment.

FIG. 15 is a flowchart illustrating a specific example of an operation at the time of logical page write of the memory system according to the first embodiment.

FIG. 16 is a block diagram illustrating an example of a hardware configuration of a memory controller included in a memory system according to a second embodiment.

FIG. 17 is a flowchart illustrating an example of a patrol operation of the memory system according to the second embodiment.

### DETAILED DESCRIPTION

In general, according to one embodiment, a memory system includes a memory device, a memory controller, a power supply circuit, and a power storage device. The memory device is configured to store data in a nonvolatile manner. The memory controller is configured to control the memory device. The power supply circuit is configured to generate power for driving the memory device and the memory controller based on power supplied from an external power supply, and supply the generated power to the memory device and the memory controller. The power storage device is configured to be capable of storing electric energy and to supply the electric energy to the memory device and the memory controller through the power supply circuit in a case where power supply from the external power supply is stopped. The memory controller is further configured to apply one of a first write mode and a second write mode having different power consumption to a write operation for the memory device according to a power storage capacity of the power storage device.

Hereinafter, embodiments will be described with reference to the drawings. Each embodiment exemplifies a device and a method for embodying the technical idea of the invention. The drawings are schematic or conceptual. The illustration of the configuration is omitted as appropriate. Components having substantially the same functions and configurations are denoted by the same reference numerals. Numbers and the like added to reference numerals are referred to by the same reference numerals and are used to distinguish between similar elements.

### <1> First Embodiment

A first embodiment relates to a memory system 1 configured to select a more preferable data write method according to a state of a power storage device necessary for realizing a power loss protection (PLP) function. Hereinafter, details of the memory system 1 according to the first embodiment will be described.

### <1-1> Configuration

First, a configuration of the memory system 1 according to the first embodiment will be described.

### <1-1-1> Configuration of Memory System 1

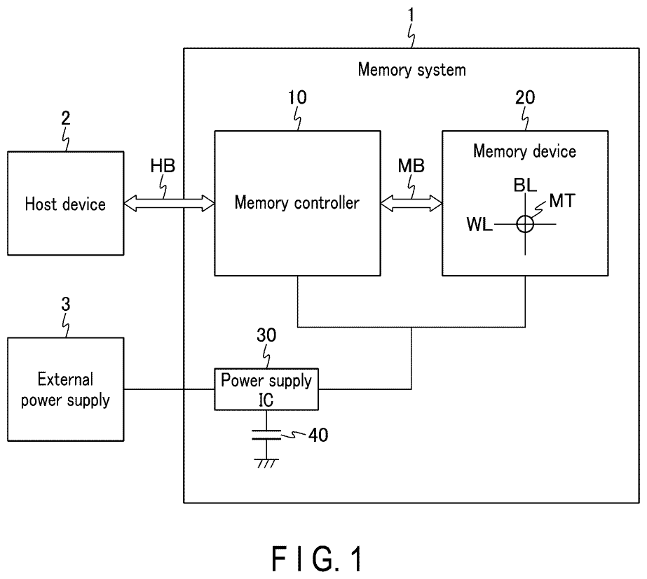

FIG. 1 is a block diagram illustrating an example of the configuration of the memory system according to the first embodiment. As illustrated in FIG. 1, the memory system 1 can be connected to an external host device 2 and an external power supply 3. The memory system 1 is a storage device such as a memory card, a solid state drive (SSD), or a universal flash storage (UFS) device. The host device 2 is an electronic device such as a personal computer, a personal digital assistant, or a server. The host device 2 may be simply referred to as a “host”. The external power supply 3 is a power supply source for the memory system 1.

The memory system 1 includes, for example, a memory controller 10, at least one memory device 20, a power supply integrated circuit (IC) 30, and a power storage device 40.

The memory controller 10 is, for example, a semiconductor integrated circuit configured as a system on a chip (SoC), an application specific integrated circuit (ASIC), or a field-programmable gate array (FPGA). The memory controller 10 has a function of managing and controlling the memory device 20. The memory controller 10 is configured to be connected to the host device 2 through a host bus HB. The memory controller 10 is connected to the memory device 20 through a memory bus MB. The memory controller 10 can control the memory device 20 based on requests received from the host device 2.

The memory device 20 is a semiconductor memory device configured to store data in a nonvolatile manner. The memory device 20 is, for example, a NAND flash memory. In the NAND flash memory, a unit of a data read operation and a data write operation is referred to as a page. The memory device 20 includes a plurality of memory cell transistors MT, a plurality of bit lines BL, and a plurality of word lines WL. For example, each memory cell transistor MT is associated with one bit line BL and one word line WL. A column address is allocated to each bit line BL. A page address is assigned to each word line WL.

The power supply IC 30 generates power for driving a plurality of electric circuit components included in the memory system 1 based on the power supplied from the external power supply 3. The plurality of electric circuit components includes the memory controller 10 and the memory device 20. Then, the power supply IC 30 supplies the generated power to each of the electric circuit components. The power supply IC 30 may be referred to as a power supply circuit. For example, the power supply IC 30 generates, as power, a plurality of different voltages to be power supply voltages of the plurality of electric circuit components. The power supply IC 30 may generate power for driving other electric circuit components (not illustrated).

The power storage device 40 can store electric energy. The power storage device 40 is, for example, a chargeable capacitor or battery. The power storage device 40 is charged by the power supply IC 30 in a case where power is supplied from the external power supply 3 to the memory system 1. In a case where the power storage device 40 is a capacitor, an arbitrary capacitor can be used. For example, as the power storage device 40, an electrolytic capacitor, a tantalum capacitor, a multilayer ceramic capacitor, or an electrical double-layer capacitor can be adopted.

In the present specification, data instructed to be written by the host device 2 is referred to as “write data”. In addition, data read from the memory device 20 is referred to as “read data”.

In the memory system 1, in a case where the power supply from the external power supply 3 is stopped, the power supply IC 30 switches the power supply source to the plurality of electric circuit components included in the memory system 1 from the external power supply 3 to the power storage device 40. As a result, the electric energy stored in the power storage device 40 is supplied to at least each of the memory controller 10 and the memory device 20 through the power supply IC 30. Therefore, each of the memory controller 10 and the memory device 20 can operate by the electric energy stored in the power storage device 40 for a while even after the power supply from the external power supply 3 is stopped. At this time, the memory controller 10 executes the PLP operation using the electric energy stored in the power storage device 40. In the PLP operation, the memory controller 10 saves data stored in a volatile memory to be described later to a nonvolatile memory (the memory device 20).

Note that the power supply IC 30 may monitor the voltage supplied from the external power supply 3 in order to detect that the power supply from the external power supply 3 is stopped. For example, in a case where the voltage supplied from the external power supply 3 falls below a predetermined level, the power supply IC 30 determines that the power-off has occurred, and transmits a power-off signal to the memory controller 10. Then, the power supply IC 30 switches the power supply source from the external power supply 3 to the power storage device 40, and the memory controller 10 starts the PLP operation.

Note that the power supply IC 30 may not be configured to detect the power-off. For example, the memory controller 10 may detect the power-off. The stop of the power supply from the external power supply 3 may be notified the memory system 1 by the host device 2. In a case of receiving the notice of the stop of the power supply from the external power supply 3, the memory controller 10 can execute the shutdown operation of the memory system 1 including the processing similar to the PLP operation according to the notice content.

### <1-1-2> Hardware Configuration of Memory Controller 10

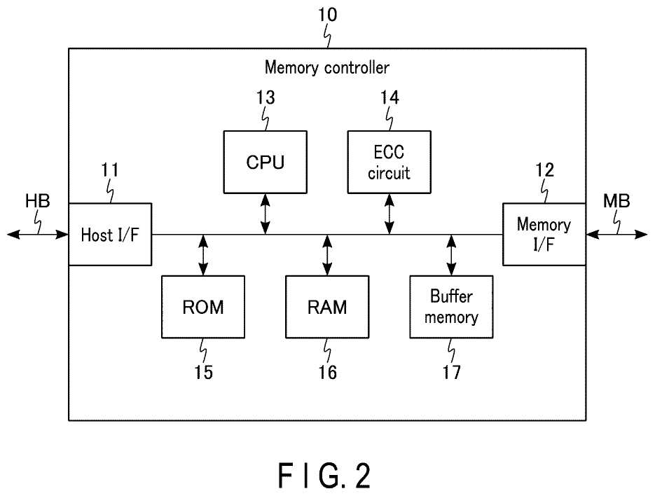

FIG. 2 is a block diagram illustrating an example of a hardware configuration of the memory controller 10 included in the memory system 1 according to the first embodiment. As illustrated in FIG. 2, the memory controller 10 includes, for example, a host interface (host I/F) 11, a memory interface (memory I/F) 12, a central processing unit (CPU) 13, an error correction code (ECC) circuit 14, a read only memory (ROM) 15, a random access memory (RAM) 16, and a buffer memory 17. The host interface 11, the memory interface 12, the CPU 13, the error check and correction circuit 14, the ROM 15, the RAM 16, and the buffer memory 17 may be connected to an internal bus.

The host interface 11 controls communication according to an interface standard between the host device 2 and the memory controller 10. The host interface 11 is connected to the host device 2 through the host bus HB. The host interface 11 supports interface standards such as a Serial Advanced Technology Attachment (SATA), a Serial Attached SCSI (SAS), a PCI Express (PCIe™), and a Non-Volatile Memory Express™ (NVMe™).

The memory interface 12 controls communication according to an interface standard between the memory controller 10 and the memory device 20. The memory interface 12 is connected to the memory device 20 through a memory bus MB. The memory interface 12 supports interface standards such as Toggle DDR and Open NAND Flash Interface (ONFI).

The CPU 13 controls the entire operation of the memory controller 10. For example, the CPU 13 instructs the memory device 20 to perform a data write operation through the memory interface 12 according to a write request received through the host interface 11. The CPU13 instructs the memory device 20 to perform a data read operation through the memory interface 12 according to a read request received through the host interface 11. For example, the CPU13 is a processor capable of executing a program for controlling the memory controller 10.

The error check and correction circuit 14 is a circuit that executes processing related to data error correction. In the write operation, the error check and correction circuit 14 generates a parity for each page of write data received from the host device 2. The generated parity is added to the write data and written to the memory device 20. In a read operation, the error check and correction circuit 14 generates a syndrome based on read data (a set of data and parity) received from the memory device 20. Then, the error check and correction circuit 14 detects an error in the read data based on the generated syndrome and corrects the detected error.

The ROM 15 stores, for example, a program such as firmware. As the ROM 15, for example, a nonvolatile memory such as an Electrically Erasable Programmable Read-Only Memory (EEPROM™) is used. The CPU 13 executes various processing by executing firmware stored in the ROM 15 or the like.

The RAM 16 is a memory device used as a work area of the CPU 13. The RAM 16 stores, for example, a lookup table (LUT) for managing a storage area of the memory device 20. The LUT includes, for example, information in which a logical address (logical page) of a data storage destination is associated with a physical address. The LUT is appropriately rewritten according to the operation of the memory system 1. The LUT is read from the memory device 20 at the time of powering on the memory system 1. The LUT is stored in the memory device 20 at the time of powering off the memory system 1. The CPU 13 may generate a difference of the LUT and appropriately back up the difference in the memory device 20. The RAM16 is an example of a volatile memory. As the RAM 16, for example, a dynamic random access memory (DRAM), a static random access memory (SRAM), or the like is used. The RAM 16 may be provided outside the memory controller 10.

The buffer memory 17 is a memory device that is also used as a temporary storage area. The buffer memory 17 temporarily stores, for example, write data received from the host device 2, read data received from the memory device 20, and the like. The buffer memory 17 is an example of a volatile memory. As the buffer memory 17, for example, a DRAM, an SRAM, or the like is used. The buffer memory 17 may be provided outside the memory controller 10.

### <1-1-3> Hardware Configuration of Memory Device 20

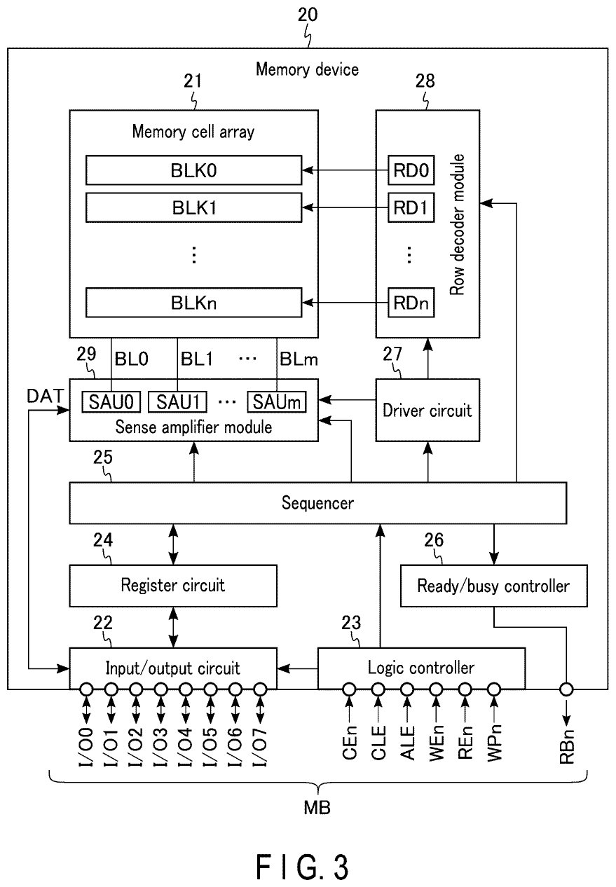

FIG. 3 is a block diagram illustrating an example of a hardware configuration of the memory device 20 included in the memory system 1 according to the first embodiment. As illustrated in FIG. 3, the memory device 20 includes, for example, a memory cell array 21, an input/output circuit 22, a logic controller 23, a register circuit 24, a sequencer 25, a ready/busy controller 26, a driver circuit 27, a row decoder module 28, and a sense amplifier module 29. Signals transmitted and received through the memory bus MB include, for example, input/output signals I/O0 to I/O7, control signals CEn, CLE, ALE, WEn, REn, and WPn, and a ready/busy signal RBn.

The memory cell array 21 is a set of a plurality of memory cell transistors MT (not illustrated). The memory cell array 21 includes a plurality of blocks BLK0 to BLKn (n is an integer of 1 or more). The block BLK is used, for example, as a unit of data erase operation. A block address is assigned to each block BLK. In the memory cell array 21, a plurality of bit lines BL0 to BLm (“m” is an integer of 1 or more) and a plurality of word lines WL (not illustrated) are provided. Note that the block BLK may be divided into sub-blocks and managed.

The input/output circuit 22 controls transmission and reception (input/output) of the input/output signals I/O0 to I/O7. The input/output signal I/O may include data DAT, status information, an address, and a command. The input/output circuit 22 can input and output the data DAT between the sense amplifier module 29 and the memory controller 10. The input/output circuit 22 can output the status information transferred from the register circuit 24 to the memory controller 10. The input/output circuit 22 can output each of the address and the command transferred from the memory controller 10 to the register circuit 24.

The logic controller 23 controls the input/output circuit 22 and the sequencer 25 based on various control signals input from the memory controller 10. For example, the logic controller 23 enables the memory device 20 based on the control signal CEn. The logic controller 23 notifies the input/output circuit 22 that the input/output signals I/O received by the memory device 20 are a command and an address based on the control signals CLE and ALE. The logic controller 23 orders the input/output circuit 22 to receive the input/output signal I/O based on the control signal WEn, and orders the input/output circuit 22 to transmit the input/output signal I/O based on the control signal REn. The logic controller 23 sets the memory device 20 to a protection state based on the control signal WPn.

The register circuit 24 temporarily stores a status, an address, a command, and the like. The status is information indicating an operation state of the memory device 20. The status is updated based on the control of the sequencer 25 and transferred to the memory controller 10 through the input/output circuit 22. The address may include a block address, a page address, a column address, and the like. The commands include instructions for various operations of the memory device 20.

The sequencer 25 controls the entire operation of the memory device 20. The sequencer 25 executes the read operation, a write operation, an erase operation, and the like based on the command and the address stored in the register circuit 24.

The ready/busy controller 26 generates the ready/busy signal RBn under the control of the sequencer 25. The ready/busy signal RBn notifies the memory controller 10 whether the memory device 20 is in a ready state or a busy state. The ready state is a state in which the memory device 20 can receive an order from the memory controller 10. The busy state is a state in which the memory device 20 cannot receive (or does not process even if receiving) an order from the memory controller 10.

The driver circuit 27 generates a voltage used in the read operation, the write operation, the erase operation, and the like. The driver circuit 27 supplies the generated voltage to the row decoder module 28, the sense amplifier module 29, and the like.

The row decoder module 28 is a circuit used for selecting the block BLK and supplying a voltage to a wiring such as the word line WL. The row decoder module 28 includes a plurality of row decoders RD0 to RDn. The row decoders RD0 to RDn are associated with the blocks BLK0 to BLKn, respectively. Each row decoder RD can set the associated block BLK to be selected or non-selected based on the block address.

The sense amplifier module 29 is a circuit used for supplying a voltage to each bit line BL and reading data. The sense amplifier module 29 includes a plurality of sense amplifier units SAU0 to SAUm. The sense amplifier units SAU0 to SAUm are associated with a plurality of bit lines BL0 to BLm, respectively. Each sense amplifier unit SAU can determine data read from the selected memory cell transistor MT based on the voltage of the associated bit line BL.

In the memory device 20, a set of the memory cell array 21, the row decoder module 28, and the sense amplifier module 29 may be referred to as a plane. The plane includes at least the memory cell array 21. The memory device 20 may include a plurality of planes. The sequencer 25 can be configured to be able to control each of the plurality of planes.

### <1-1-4> Circuit Configuration of Memory Cell Array 21

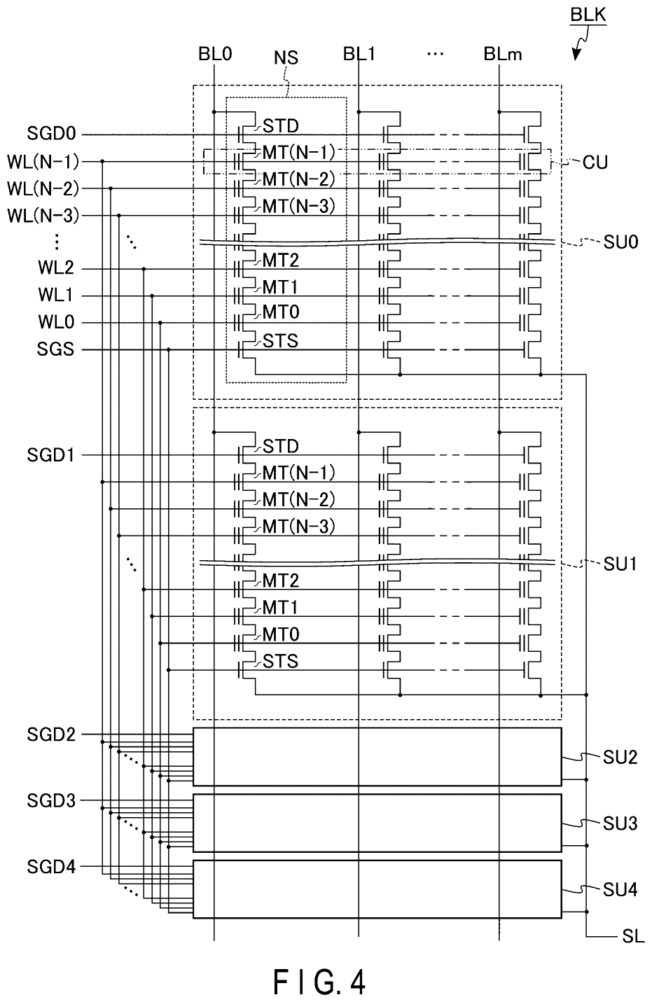

FIG. 4 is a circuit diagram illustrating an example of a circuit configuration of the memory cell array 21 included in the memory device 20 according to the first embodiment. FIG. 4 illustrates one of the plurality of blocks BLK included in the memory cell array 21. As illustrated in FIG. 4, in the block BLK, a plurality of bit lines BL0 to BLm, a plurality of word lines WL0 to WL (N−1) (N is an integer of 2 or more), select gate lines SGD0 to SGD4, a select gate line SGS, and a source line SL are provided. The select gate lines SGD0 to SGD4 and SGS and the word lines WL0 to WL (N−1) are provided for each block BLK. The bit lines BL0 to BLm are shared by a plurality of blocks BLK. The source line SL may be shared by a plurality of blocks BLK, or may be provided for each block BLK.

The block BLK includes, for example, five string units SU0 to SU4. Each string unit SU includes a plurality of NAND strings NS. The plurality of NAND strings NS is associated with the bit lines BL0 to BLm, respectively. That is, each bit line BL is shared by the plurality of NAND strings NS to which the same column address is allocated among the plurality of blocks BLK. Each NAND string NS is connected between the associated bit line BL and source line SL.

Each NAND string NS includes, for example, N memory cell transistors MT0 to MT(N−1) and select transistors STD and STS. Each memory cell transistor MT is a memory cell including a control gate and a charge storage layer, and stores data in a nonvolatile manner. A threshold voltage of the memory cell transistors MT can be changed based on the amount of charge injected into a charge storage layer or the like. Each of the select transistors STD and STS is used to select the block BLK and the string unit SU.

In each NAND string NS, the select transistor STD, the memory cell transistors MT(N−1) to MT0, and the select transistor STS are connected in series in this order. Specifically, a drain of the select transistor STD is connected to the associated bit line BL. A source of the select transistor STD is connected to a drain of the memory cell transistor MT(N−1). The memory cell transistors MT0 to MT(N−1) are connected in series between the select transistors STD and STS. A drain of the select transistor STS is connected to a source of the memory cell transistor MT0. A source of the select transistor STS is connected to the source line SL.

The select gate lines SGD0 to SGD4 are associated with the string units SU0 to SU4, respectively. Each select gate line SGD is connected to a gate of each of the plurality of select transistors STD included in the associated string unit SU. The select gate line SGS is connected to a gate of each of the plurality of select transistors STS included in the associated block BLK. The word lines WL0 to WL(N−1) are connected to the control gates of the plurality of memory cell transistors MT0 to MT(N−1) included in the associated block BLK, respectively.

In the present specification, a set of memory cell transistors MT connected to a common word line WL in one string unit SU is referred to as a cell unit CU. A set of 1-bit data stored in each of the plurality of memory cell transistors MT included in the cell unit CU is referred to as page data. That is, the “page” is associated with a set of the memory cell transistors MT connected to the common word line WL in the same block BLK. The cell unit CU can store two or more page data according to the number of bits of data stored in each memory cell transistor MT. That is, the memory controller 10 can manage a storage region of the memory device 20 in units of cell units CU configured by a plurality of memory cell transistors MT each of which can store a plurality of bit data (or multi-value data).

The memory cell array 21 may have a circuit configuration other than the above. For example, the number of string units SU included in each block BLK and the number of select transistors STD and STS included in each NAND string NS can be designed to arbitrary numbers. The select gate line SGS may be provided for each string unit SU.

### <1-1-5> Threshold Voltage Distribution of Memory Cell Transistors MT

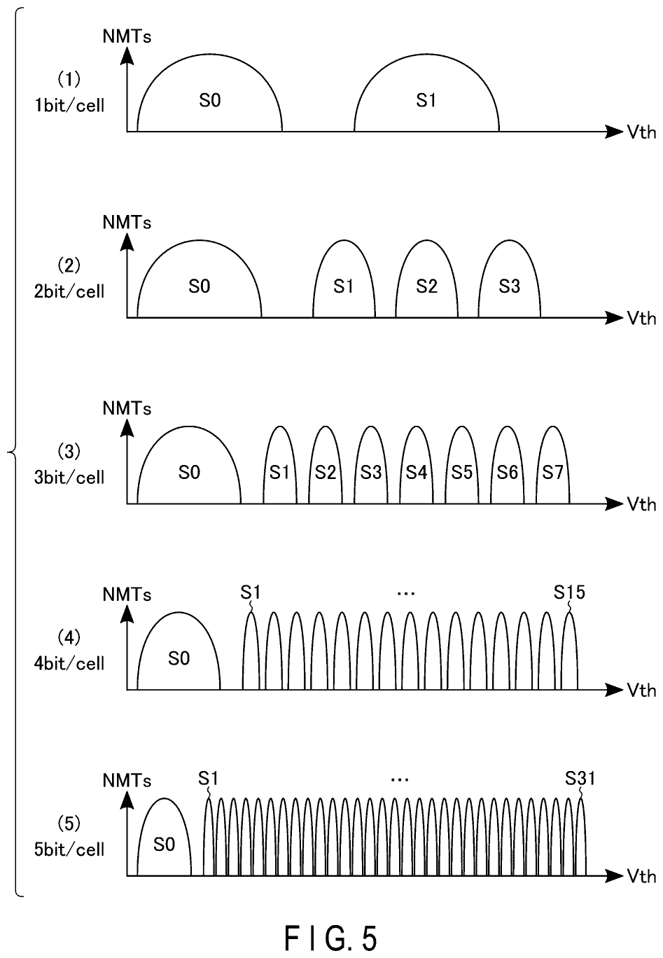

FIG. 5 is a schematic diagram illustrating an example of threshold voltage distribution of the memory cell transistors MT in the memory device 20 according to the first embodiment. (1) to (5) of FIG. 5 illustrate threshold voltage distributions of the memory cell transistors MT in a case where 1-bit data to 5-bit data are stored in the memory cell transistors MT, respectively. In each drawing illustrated in FIG. 5, a horizontal axis corresponds to a threshold voltage (Vth) of the memory cell transistors MT, and a vertical axis corresponds to the number (NMTs) of the memory cell transistors MT.

As illustrated in FIG. 5, the threshold voltage distribution of the memory cell transistors MT includes a plurality of states S. The number of states S changes according to the number of bits of data stored in each of the plurality of memory cell transistors MT included in the cell unit CU. Since randomization processing is performed on data written in each cell unit CU, the memory cell transistors MT are substantially evenly distributed in the plurality of formed states S.

In a case where 1-bit data is stored in each memory cell transistor MT (1 bit/cell), the threshold voltage distribution of the memory cell transistors MT has two states S0 and S1 as shown in (1) of FIG. 5. In 1 bit/cell, 1-bit data different from each other is allocated to each of the two states S0 and S1. Such a write method is also called a single-level cell (SLC) method.

In a case where 2-bit data is stored in each memory cell transistor MT (2 bits/cell), the threshold voltage distribution of the memory cell transistors MT has four states S0 to S3 as illustrated in (2) of FIG. 5. In 2 bits/cell, 2-bit data different from each other is allocated to each of the four states S0 to S3. Such a write method is also called a multi-level cell (MLC) method.

In a case where 3-bit data is stored in each memory cell transistor MT (3 bits/cell), the threshold voltage distribution of the memory cell transistors MT has eight states S0 to S7 as shown in (3) of FIG. 5. In 3-bits/cell, 3-bit data different from each other is allocated to each of the eight states S0 to S7. Such a write method is also called a triple-level cell (TLC) method.

In a case where 4-bit data is stored in each memory cell transistor MT (4 bits/cell), the threshold voltage distribution of the memory cell transistors MT has 16 states S0 to S15 as shown in (4) of FIG. 5. In 4 bits/cell, 4-bit data different from each other is allocated to each of the 16 states S0 to S15. Such a write method is also called a quad-level cell (QLC) method.

In a case where 5-bit data is stored in each memory cell transistor MT (5 bits/cell), the threshold voltage distribution of the memory cell transistors MT has 32 states S0 to S31 as shown in (5) of FIG. 5. In 5 bits/cell, 5-bit data different from each other is allocated to each of the 32 states S0 to S31. Such a write method is also called a penta-level Cell (PLC) method.

In each threshold voltage distribution described above, a verify voltage and a read voltage are set between adjacent states S. In the write operation, the memory device 20 repeatedly executes a set of a program operation for increasing the threshold voltage of the memory cell transistors MT and the read operation using a verify voltage. The memory device 20 can check whether the threshold voltage of the memory cell transistors MT to be programmed has reached a target state S based on the verify voltage. In the read operation, the memory device 20 executes the read operation using at least one read voltage. The memory device 20 can specify the state S corresponding to the threshold voltage of the memory cell transistor MT based on whether or not the memory cell transistor MT to which the read voltage is applied is turned on.

Note that 6-bit or more data may be stored in the memory cell transistor MT. In a case where the memory cell transistor MT stores k-bit data (k is an integer of 1 or more), at least 2^{k} states S are provided in the threshold voltage distribution of the memory cell transistors MT. In the present specification, a case where the cell unit CU stores 4-page data, that is, the case where the memory cell array 21 stores data by the QLC method will be described as an example. The 4-page data corresponds to 4-bit data.

### <1-2> Operation

Next, an operation of the memory system 1 according to the first embodiment will be described.

### <1-2-1> Outline of Two-Stage Program

The memory system 1 according to the first embodiment is configured to be capable of executing a two-stage program. The two-stage program is a write operation for executing a write operation of plural-page data in two stages in a case where the plural-page data is written to one cell unit CU. Hereinafter, a first write operation is referred to as a first stage program, and a second write operation is referred to as a second stage program, in the two-stage program. In the first stage program, the threshold voltage of the memory cell transistors MT is roughly increased according to the write data. In the second stage program, the threshold voltage of the memory cell transistors MT is finely increased according to the write data. The second stage program is executed after the first stage program is completed and after the first stage program of the adjacent cell unit CU is completed.

Specifically, upon execution of the first stage program in which the word line WLi (i is an integer of 0 or more) is selected, the threshold voltage distribution of each memory cell transistor MT connected to the word line WLi roughly rises. Then, upon execution of the first stage program in which the word line WL(i+1) is selected, the threshold voltage distribution of the memory cell transistors MT connected to the word line WLi is slightly shifted to a positive voltage side due to an inter-cell interference effect. Then, upon execution of the second stage program in which the word line WLi is selected, the threshold voltage of each memory cell transistors MT connected to the word line WLi rises from a state of being roughly written by the first stage program to a desired threshold voltage. The shift amount of the threshold voltage in the second stage program is smaller than that in the first stage program. Therefore, the inter-cell interference effect on the word line WLi by the second stage program in which the word line WL(i+1) is selected is suppressed.

The first stage program may be referred to as a rough write operation. The second stage program may be referred to as a fine write operation. Each of the first stage program and the second stage program includes an operation of applying a program voltage to the plurality of memory cell transistors MT included in the selected cell unit CU a plurality of times while stepping up the program voltage. A step-up width of the program voltage in the rough write operation is larger than a step-up width of the program voltage in the fine write operation.

The number of bits of the write data used in the first stage program may be the same as or smaller than the number of bits of the write data used in the second stage program. Hereinafter, a two-stage program in which the number of bits of write data used in each of the first stage program and the second stage program is the same is referred to as a Foggy-Fine method. A two-stage program in which the MLC method is used in the first stage program and the storage method of 3 bits/cell or more is used in the second stage program is referred to as an MLC-Fine method.

### (1: Write Order of Two-Stage Program)

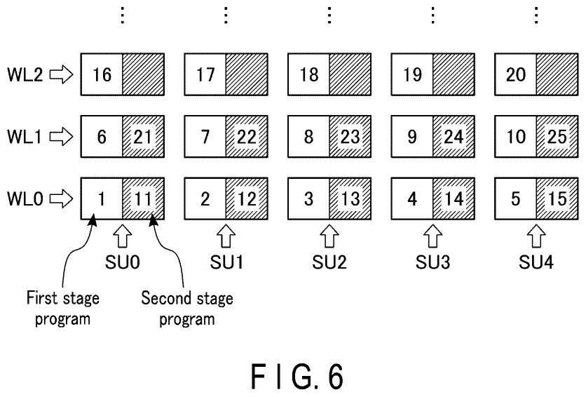

FIG. 6 is a schematic diagram illustrating an example of the write order of the two-stage program in the memory system 1 according to the first embodiment. FIG. 6 illustrates the combination of the word line WL and the string unit SU in a certain block BLK and the order in which each of the first stage program and the second stage program is executed. In the following description, the write operation in which a specific cell unit CU is selected can be executed by selecting one word line WL and one string unit SU.

As illustrated in FIG. 6, first, the memory controller 10 causes the memory device 20 to sequentially execute the first stage program in which the word line WL0 and each of the string units SU0 to SU4 are selected (“1” to “5” in FIG. 6). Next, the memory controller 10 causes the memory device 20 to sequentially execute the first stage program in which the word line WL1 and each of the string units SU0 to SU4 are selected (“6” to “10” in FIG. 6). Next, the memory controller 10 causes the memory device 20 to sequentially execute the second stage program in which the word line WL0 and each of the string units SU0 to SU4 are selected (“11” to “15” in FIG. 6). Next, the memory controller 10 causes the memory device 20 to sequentially execute the first stage program in which the word line WL2 and each of the string units SU0 to SU4 are selected (“16” to “20” in FIG. 6). Next, the memory controller 10 causes the memory device 20 to sequentially execute the second stage program in which the word line WL1 and each of the string units SU0 to SU4 are selected (“21” to “25” in FIG. 6). Hereinafter, similarly, the first stage program and the second stage program are alternately executed.

The write order in the two-stage program may be another order. In the memory system 1, the second stage program of each cell unit CU may be executed after the first stage program of the adjacent cell unit CU is executed. In the above description, the case where the memory controller 10 executes the write operation in ascending order of the number of the word lines WL (from the source line SL side) has been exemplified, but the present invention is not limited thereto. The memory controller 10 may be configured to execute the write operation in descending order of the number of the word lines WL (from the bit line BL side).

### (2: Foggy-Fine Method)

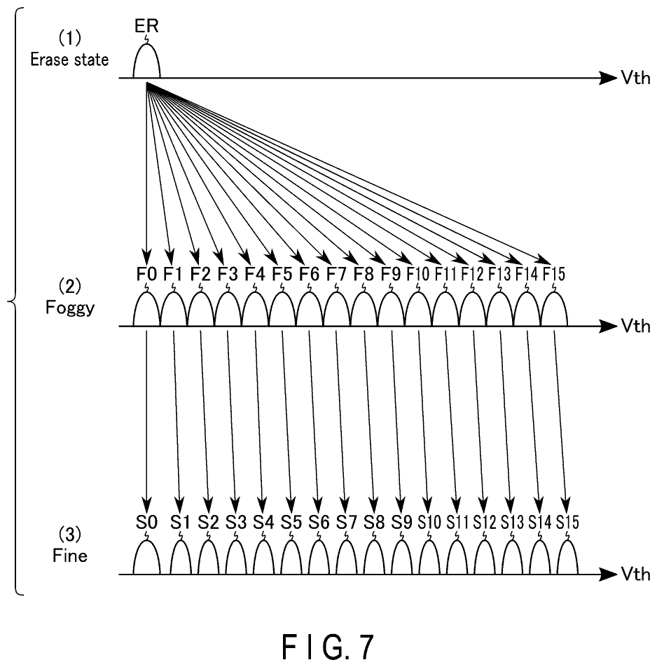

FIG. 7 is a schematic diagram illustrating an outline of the write operation using the Foggy-Fine method in the memory system 1 according to the first embodiment. (1) of FIG. 7 illustrates the threshold voltage distribution of the memory cell transistors MT in an erase state. (2) of FIG. 7 illustrates the threshold voltage distribution of the memory cell transistors MT after the first stage program in the Foggy-Fine method is executed. (3) of FIG. 7 illustrates the threshold voltage distribution of the memory cell transistors MT after the second stage program in the Foggy-Fine method is executed.

As illustrated in (1) of FIG. 7, in the erase state, the threshold voltages of the plurality of memory cell transistors MT in the cell unit CU are distributed in a state ER.

As illustrated in (2) of FIG. 7, in the first stage program in the Foggy-Fine method, the memory controller 10 causes the memory device 20 to execute a rough write operation using 4-page data to be written stored in the buffer memory 17. As a result, 16 states F0 to F15 are formed from the state ER.

As illustrated in (3) of FIG. 7, in the second stage program in the Foggy-Fine method, the memory controller 10 causes the memory device 20 to execute a fine write operation using 4-page data stored in the buffer memory 17 and similar to that of the first stage program. As a result, states S0 to S15 are formed from the states F0 to F15, respectively. The states F0 to F15 are lower than any of the corresponding states S of the states S0 to S15 and are widely distributed. Upon completion of the second stage program in the Foggy-Fine method, the 4-page data written to the memory device 20 can be discarded from the buffer memory 17.

As described above, in the Foggy-Fine method, 4-page data to be written is stored in the buffer memory 17 until the second stage program is executed, and a large capacity of a write cache allocated to the buffer memory 17 is required. On the other hand, the Foggy-Fine method can suppress the inter-cell interference effect more than other methods of the two-stage program.

### (3: MLC-Fine Method)

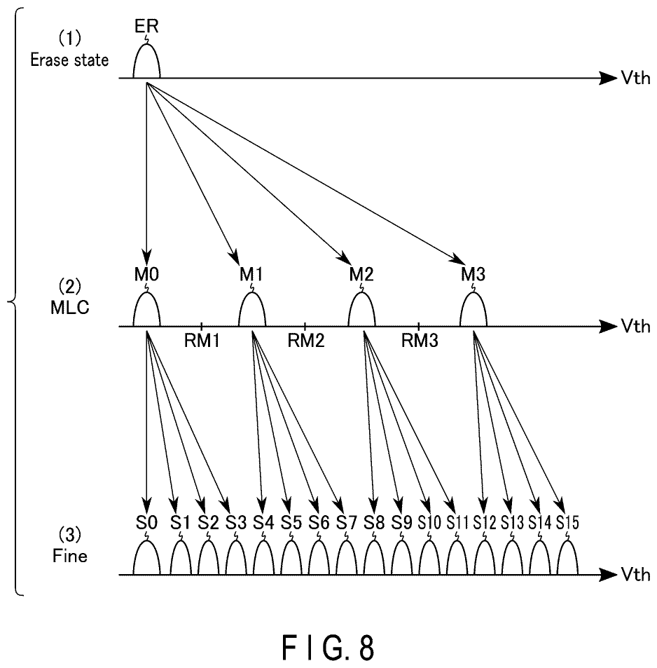

FIG. 8 is a schematic diagram illustrating an outline of a write operation using an MLC-Fine method in the memory system according to the first embodiment. (1) of FIG. 8 illustrates the threshold voltage distribution of the memory cell transistors MT in an erase state. (2) of FIG. 8 illustrates the threshold voltage distribution of the memory cell transistors MT after the first stage program in the MLC-Fine method is executed. (3) of FIG. 8 illustrates the threshold voltage distribution of the memory cell transistors MT after the second stage program in the MLC-Fine method is executed.

As illustrated in (1) of FIG. 8, in the erase state, the threshold voltages of the plurality of memory cell transistors MT in the cell unit CU are distributed in a state ER. A state of (1) of FIG. 8 is similar to the state of (1) of FIG. 7.

As illustrated in (2) of FIG. 8, in the first stage program in the MLC-Fine method, the memory controller 10 causes the memory device 20 to execute a rough write operation using 2-page data to be written stored in the buffer memory 17 among 4-page data to be written. As a result, four states M0 to M3 are formed from the state ER. In this example, a read voltage RM1 is set between the states M0 and M1. A read voltage RM2 is set between the states M1 and M2. A read voltage RM3 is set between the states M2 and M3. Upon completion of the first stage program in the MLC-Fine method, the 2-page data written in the memory device 20 can be discarded from the buffer memory 17.

As illustrated in (3) of FIG. 8, in the second stage program in the MLC-Fine method, the memory controller 10 first reads data written by the first stage program from the memory device 20. At this time, the memory device 20 executes the read operation using the read voltages RM1, RM2, and RM3. Such an operation is also called internal data load (IDL). Then, the memory controller 10 causes the memory device 20 to execute a fine write operation using the 2-page data read by the IDL and 2-page data newly stored in the buffer memory 17. As a result, the four states S0 to S3 are formed from the state M0. The four states S4 to S7 are formed from the state M1. The four states S8 to S11 are formed from the state M2. The four states S12 to S15 are formed from the state M3. The state M0 is distributed similarly to the state ER, for example. The state M1 is lower than the state S4 and is widely distributed, for example. The state M2 is lower than the state S8 and is widely distributed, for example. The state M3 is lower than the state S12 and is widely distributed, for example. Upon completion of the second stage program in the MLC-Fine method, the 2-page data remaining in the buffer memory 17 among the 4-page data to be written can be discarded.

As described above, in the MLC-Fine method, the buffer memory 17 uses only data for 2 pages in both the execution of the first stage program and the execution of the second stage program. Therefore, the MLC-Fine method can reduce the required amount of the write cache.

### <1-2-2> Outline of Write Sequence

Next, an outline of a data write sequence in the memory system 1 will be described using a functional configuration of the memory controller 10.

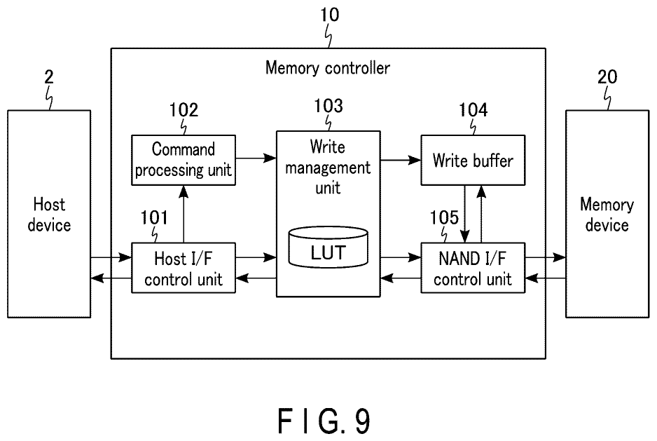

FIG. 9 is a block diagram illustrating an example of a functional configuration of the memory controller 10 according to the first embodiment. As illustrated in FIG. 9, the memory controller 10 includes a host interface (I/F) control unit 101, a command processing unit 102, a write management unit 103, a write buffer 104, and a NAND interface (I/F) control unit 105.

The host interface control unit 101 controls communication between the host device 2 and the memory controller 10 using the host interface 11. Upon receiving a command from the host device 2, the host interface control unit 101 transfers the received command to the command processing unit 102. Upon receiving write data from the host device 2, the host interface control unit 101 transfers the received write data to the write management unit 103.

The command processing unit 102 processes a command received from the host device 2. Upon receiving a write command from the host device 2, the command processing unit 102 instructs the write management unit 103 to perform a write operation based on the write command.

The write management unit 103 allocates a logical page to the write data based on the received write command and the write data. Then, the write management unit 103 transmits a write command to the NAND interface control unit 105. The write management unit 103 stores the write data in the write buffer 104. For example, at a time of storing the write data in the write buffer 104, the write management unit 103 returns a write completion response to the host device 2 through the host interface control unit 101.

The NAND interface control unit 105 transmits the write command and the write data stored in the write buffer 104 to the memory device 20 at the time of the write operation. In a case of receiving the read data from the memory device 20 at the time of IDL, the NAND interface control unit 105 may transfer the read data to the write buffer 104. In addition, in the case of receiving information indicating whether the write operation is normally completed from the memory device 20, the NAND interface control unit 105 transfers the information to the write management unit 103. In a case where the write operation is not normally completed, the write management unit 103 allocates the write data to another logical page and executes the write operation again. The write management unit 103 updates the lookup table (LUT) after completion of writing the write data to the memory device 20.

In a case where unintended power-off occurs in the memory system 1, it is necessary to store (non-volatilize) the write data in the write buffer 104 treated as the write completion by notifying the host device 2 of the write completion in the memory device 20. The write data in the write buffer 104 can be guaranteed by the PLP operation including this operation.

### <1-2-3> Write Method Setting Operation

The memory system 1 according to the first embodiment periodically executes a patrol operation. In addition, the memory system 1 checks a suppliable energy (capacity) of the power storage device 40 along with the patrol operation. Then, the memory system 1 switches the write method of the memory system 1 based on the capacity of the power storage device 40.

### (1: Relationship Between Use Period of Power Storage Device 40 and Suppliable Energy)

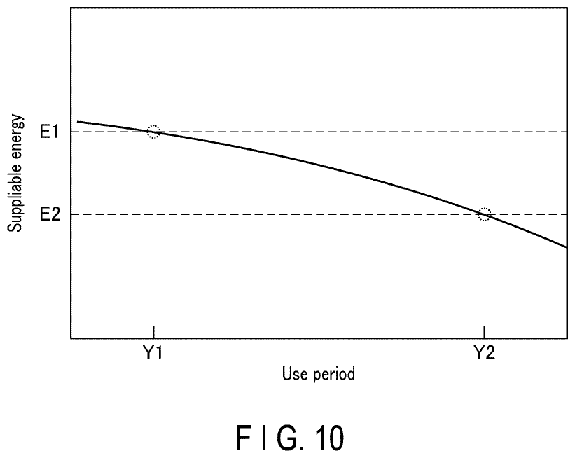

FIG. 10 is a graph showing an example of a relationship between a use period of the power storage device 40 and a suppliable energy in the memory system 1 according to the first embodiment. FIG. 10 shows a state of aged deterioration of the power storage device 40 in a case where an electrolytic capacitor is used as the power storage device 40. As shown in FIG. 10, the suppliable energy of the power storage device 40 is E1 in a case where the use period is Y1. If the use period becomes Y2, the suppliable energy of the power storage device 40 decreases from E1 to E2. In a case where a product warranty period of the memory system 1 is Y2, the power storage device 40 needs to be configured to have a power storage capacity capable of executing a desired PLP operation if the use period is Y2. Note that the desired PLP operation indicates a PLP operation in which the amount of data to be non-volatilized can be non-volatilized.

In the memory system 1, energy required for the PLP operation is larger in the Foggy-Fine method than in the MLC-Fine method. For example, as long as the suppliable energy of the power storage device 40 is E1 or more, the memory system 1 can complete the desired PLP operation at the time of power-off by using either the Foggy-Fine method or the MLC-Fine method. On the other hand, in a case where the suppliable energy of the power storage device 40 decreases to less than E1, the memory system 1 may not be able to complete the PLP operation by the Foggy-Fine method at the time of power-off. For example, there is a possibility that the memory system 1 can complete the desired PLP operation by the Foggy-Fine method if the suppliable energy of the power storage device 40 is slightly lower than E1, but thereafter, if the suppliable energy of the power storage device 40 decreases, the memory system 1 cannot perform the desired PLP operation by the Foggy-Fine method.

On the other hand, even if the suppliable energy of the power storage device 40 falls below E1, the memory system 1 can complete the desired PLP operation until the product warranty period by using the MLC-Fine method.

In a case where the write method to the memory device 20 is static, the write method that can be used in the memory system 1 is set according to the suppliable energy of the power storage device 40. For example, in order to establish the PLP operation in the period up to Y2 which is the product warranty period of the memory system 1, it is necessary to use the MLC-Fine method. However, in consideration of performance, in a case where there is sufficient suppliable energy of the power storage device 40 (for example, in the case of E1 or more), the Foggy-Fine method is preferably used. Therefore, the memory system 1 according to the first embodiment switches the write method of the memory system 1 based on the suppliable energy of the power storage device 40 in periodically execution of the patrol operation.

### (2: Sequence of Patrol Operation)

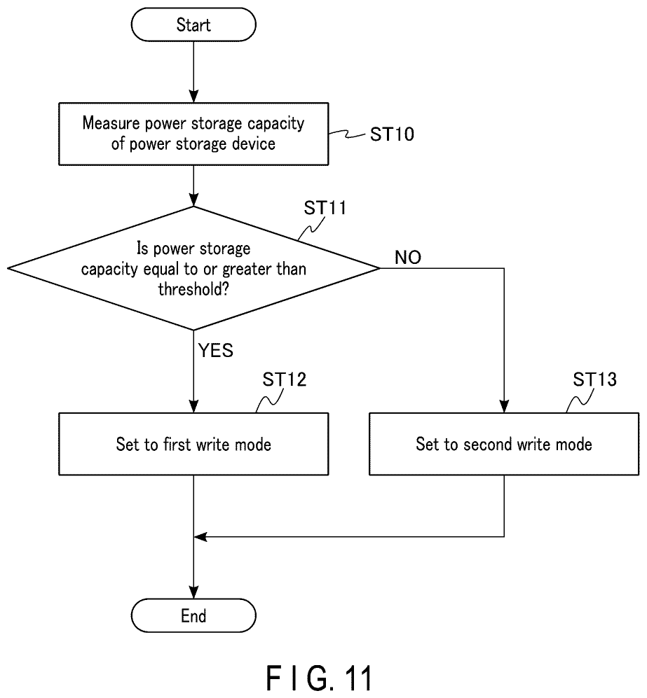

FIG. 11 is a flowchart illustrating an example of a patrol operation of the memory system 1 according to the first embodiment. The memory system 1 according to the first embodiment starts a series of operations illustrated in FIG. 11 based on a predetermined schedule, that is, periodically (Start).

In the patrol operation, the memory system 1 first measures the power storage capacity (suppliable energy) of the power storage device 40 (ST10).

Next, the memory system 1 checks whether or not the power storage capacity of the power storage device 40 is equal to or greater than a threshold (ST11).

In a case where the power storage capacity is equal to or greater than the threshold (ST11: YES), the memory system 1 is set to the first write mode (ST12).

In a case where the power storage capacity is less than the threshold (ST11: NO), the memory system 1 is set to the second write mode (ST13).

Upon completion of the processing of ST12 or ST13, the memory system 1 ends the series of operations shown in FIG. 11 (End).

In the first write mode, it is only required to use a write method that requires more energy (power consumption) than in the second write mode and has high reliability of written data. The first write mode corresponds to, for example, the Foggy-Fine method. The second write mode corresponds to, for example, the MLC-Fine method.

In the memory system 1, a subject executing the patrol operation may be the memory controller 10 or cooperation between the memory controller 10 and the power supply IC 30. The power supply IC 30 may be configured to periodically measure the power storage capacity and transmit information regarding the power storage capacity of the power storage device 40 to the memory controller 10. In this case, the memory controller 10 sets the memory system 1 to the first write mode or the second write mode based on the information regarding the power storage capacity of the power storage device 40 received from the power supply IC 30. The patrol operation is executed at a frequency of once every 15 minutes based on, for example, the Open Compute Project (OCP) standard.

### (3: Method of Checking Power Storage Capacity)

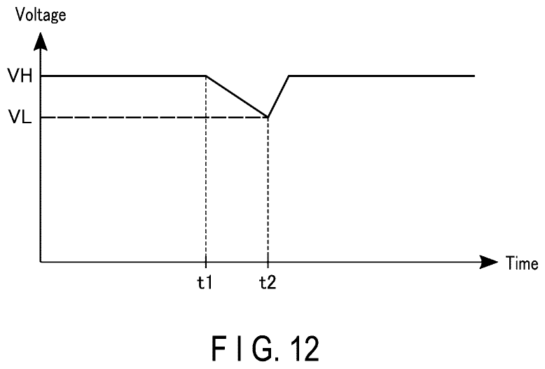

FIG. 12 is a waveform chart showing an example of a method of checking the power storage capacity of the power storage device 40 in the memory system 1 according to the first embodiment. In a graph shown in FIG. 12, a horizontal axis represents time, and a vertical axis represents a charge voltage of the power storage device 40. In measuring the power storage capacity of the power storage device 40, for example, before time t1, the power supply IC 30 first checks whether a charge voltage of the power storage device 40 is equal to or greater than a threshold voltage VL. In a case where the charge voltage of the power storage device 40 is not equal to or greater than the threshold voltage VL, the power supply IC 30 charges the power storage device 40. In this example, the charge voltage of the charged power storage device 40 is indicated by VH.

Then, at time t1, the power supply IC 30 forcibly discharges the power storage device 40 with a constant current until the charge voltage of the power storage device 40 falls below the threshold voltage VL. In this example, at time t2, the charge voltage of the power storage device 40 decreases to VL. In this case, the power supply IC 30 measures the discharge time of the power storage device 40 based on the times t1 and t2. Then, the power supply IC 30 can calculate the power storage capacity of the power storage device 40 based on the obtained discharge time, a value of the constant current (discharge current), the threshold voltage VL, and the following expression (1).

Power storage capacity=(discharge current×discharge time)/VL (1)

### <1-2-4> Specific Examples

Hereinafter, a specific example of the patrol operation and the write control in the memory system 1 according to the first embodiment will be described.

### (1: Patrol Operation)

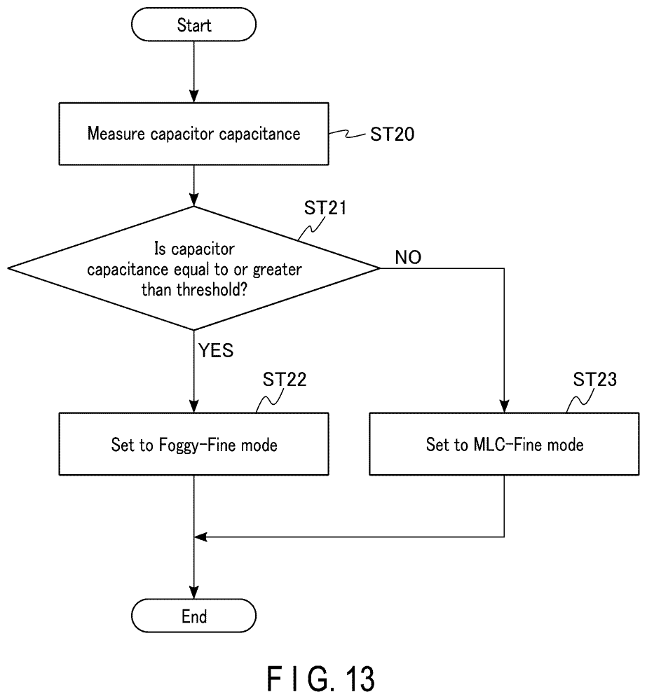

FIG. 13 is a flowchart illustrating a specific example of the patrol operation of the memory system 1 according to the first embodiment. In this example, an electrolytic capacitor is used as the power storage device 40. The memory system 1 starts a series of operations illustrated in FIG. 13 based on a predetermined schedule (Start).

In the patrol operation, for example, the power supply IC 30 first measures a capacitor capacitance of the electrolytic capacitor (power storage device 40) (ST20). For the measurement of the capacitor capacitance, for example, the method described with reference to FIG. 12 is used.

Then, the memory controller 10 or the power supply IC 30 checks whether or not the capacitor capacitance of the electrolytic capacitor is equal to or greater than a threshold (ST21).

In a case where the capacitor capacitance is equal to or greater than the threshold (ST21: YES), the memory controller 10 sets its own operation mode to the Foggy-Fine mode in which the Foggy-Fine method is applied to the write operation (ST22).

In a case where the capacitor capacitance is less than the threshold (ST21: NO), the memory controller 10 sets its own operation mode to the MLC-Fine mode in which the MLC-Fine method is applied for the write operation (ST23).

Upon completion of the processing of ST22 or ST23, the memory system 1 ends the series of operations shown in FIG. 13 (End).

### (2: Time of Supplying Logical Block)

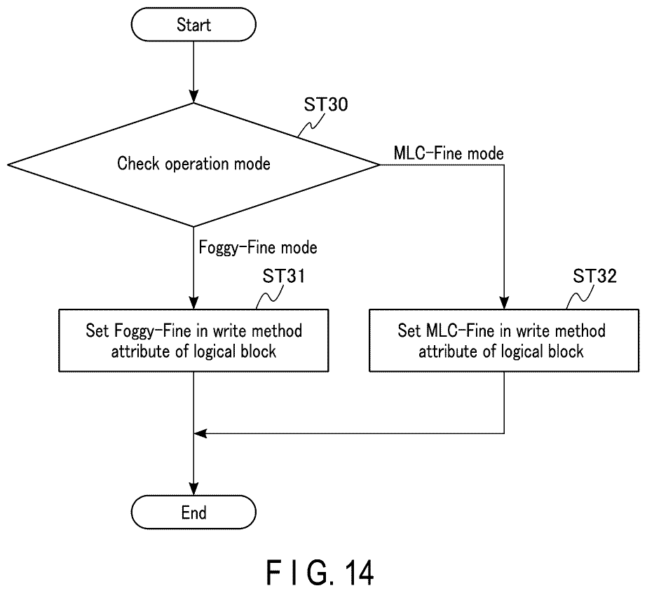

FIG. 14 is a flowchart illustrating a specific example of the operation of the memory system 1 according to the first embodiment at the time of supplying a logical block. The logical block is allocated to each block BLK. Upon receiving the write order and the write data from the host device 2, the memory controller 10 starts a series of operations shown in FIG. 14 as operations at the time of supplying a logical block (Start).

At the time of logical block supply, the memory controller 10 first checks an operation mode (ST30). This operation mode indicates a write method, and is, for example, a Foggy-Fine mode, an MLC-Fine mode, or the like.

In a case where the operation mode is the Foggy-Fine mode, the memory controller 10 sets Foggy-Fine in the write method attribute of the logical block (ST31).

In a case where the operation mode is the MLC-Fine mode, the memory controller 10 sets MLC-Fine in the write method attribute of the logical block (ST32).

Upon completion of the processing of ST31 or ST32, the memory controller 10 ends the series of operations shown in FIG. 14 (End).

### (3: Logical Page Write Time)

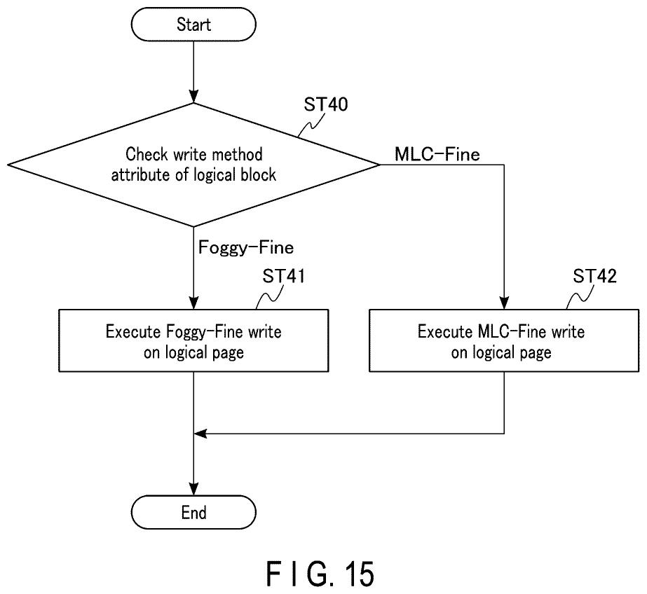

FIG. 15 is a flowchart illustrating a specific example of an operation at the time of writing a logical page of the memory system according to the first embodiment. The memory controller 10 starts a series of operations illustrated in FIG. 15 in writing the multi-page data stored in the buffer memory 17 and to which the logical page is allocated to the memory device 20 (Start).

At the time of writing the logical page, the memory controller 10 first checks the write method attribute of the logical block (ST40).

In a case where the write method attribute is Foggy-Fine, the memory controller 10 executes Foggy-Fine write on the logical page (ST41). In other words, in the processing of ST41, the memory controller 10 selects the page address of the memory device 20 corresponding to the logical page and executes the write operation of the Foggy-Fine method.

In a case where the write method attribute is MLC-Fine, the memory controller 10 executes MLC-Fine write on the logical page (ST42). In other words, in the processing of ST42, the memory controller 10 selects the page address of the memory device 20 corresponding to the logical page and executes the write operation of the MLC-Fine method.

Upon completion of the processing of ST41 or ST42, the memory controller 10 ends the series of operations shown in FIG. 15 (End).

### <1-3> Advantageous Effects of First Embodiment

As described above, the memory system 1 according to the first embodiment is configured to be able to use a plurality of write methods (for example, Foggy-Fine/MLC-Fine) having different reliability characteristics. In the MLC-Fine method, the amount of data to be stored in the memory device 20 decreases during the PLP operation in which it is necessary to store (non-volatilize) all the write caches in the memory device 20. Therefore, the MLC-Fine method can suppress energy (power consumption) required for the PLP operation more than the Foggy-Fine method. Then, the memory controller 10 includes firmware having a function of determining an appropriate write method to the memory device 20 according to the power storage capacity of the power storage device 40, and can dynamically switch the write method to the memory device 20 according to the determination result.

As a result, the memory system 1 can use the Foggy-Fine method in a case where the power storage device 40 is not deteriorated over time, and can improve the write performance and reliability. In addition, in a case where the power storage device 40 is deteriorated over time, the memory system 1 can guarantee the completion of the PLP operation at the time of power-off by using the MLC-Fine method, and can avoid the loss of write data.

Therefore, the memory system 1 according to the first embodiment can realize the PLP function within a device guarantee period and improve the reliability and performance of the device to the extent possible. Note that the operation of changing the write method described in the first embodiment is more effective as the number of formed states is larger. For example, in a case where the QLC method is used, it is preferable to use the Foggy-Fine method that achieves both high performance and high reliability. Therefore, by applying the operation described in the first embodiment, a higher effect can be obtained.

### <2> Second Embodiment

A second embodiment relates to a memory system 1 configured to select a more preferable data write method based on a use time of the memory system 1. Hereinafter, details of the memory system 1 according to the second embodiment will be mainly described on differences from the first embodiment.

### <2-1> Configuration

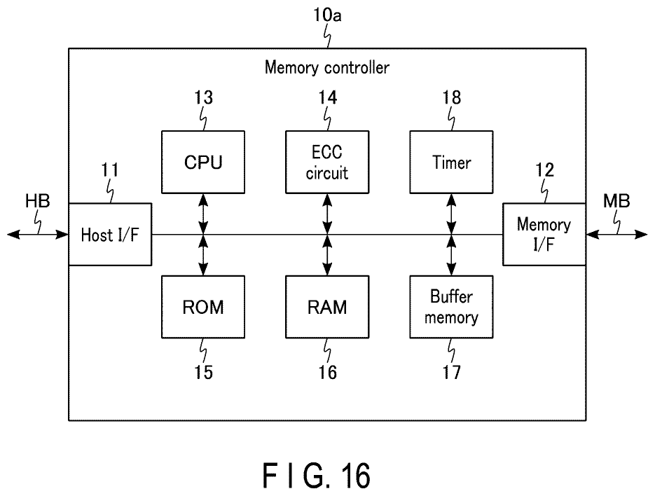

FIG. 16 is a block diagram illustrating an example of a hardware configuration of a memory controller 10a included in the memory system 1 according to the second embodiment. As illustrated in FIG. 16, the memory controller 10a has a configuration in which a timer 18 is added to the memory controller 10 according to the first embodiment. The timer 18 is configured to count an operating time of the memory system 1. Other configurations of the memory system 1 according to the second embodiment are similar to those of the first embodiment.

### <2-2> Operation

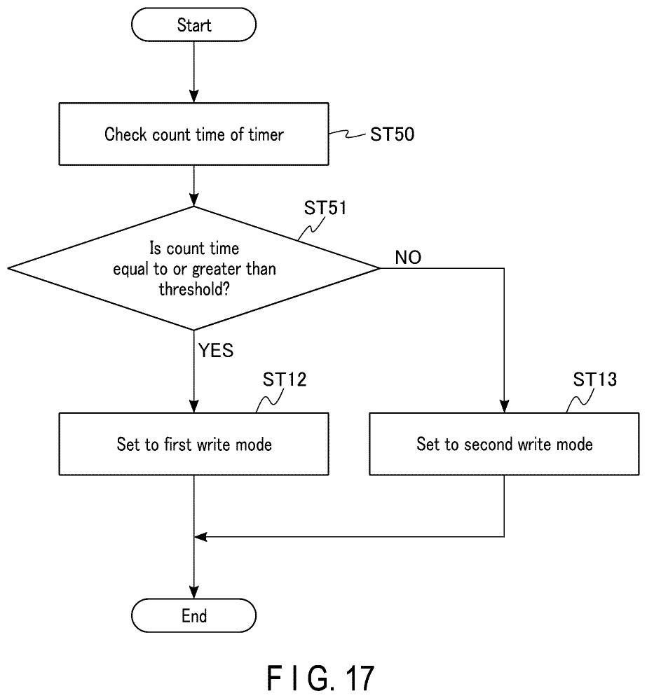

FIG. 17 is a flowchart illustrating an example of a patrol operation of the memory system 1 according to the second embodiment. The memory system 1 according to the second embodiment starts a series of operations illustrated in FIG. 17 based on a predetermined schedule (Start).

In the patrol operation, the memory controller 10a first checks a count time of the timer 18 (ST50).

Next, the memory controller 10a checks whether or not the count time of the timer 18 is equal to or greater than a threshold (ST51). This threshold is set to, for example, a limit time at which the power storage capacity of the power storage device 40 is estimated to be able to use the Foggy-Fine method during the PLP operation.

In a case where the count time is equal to or greater than the threshold (ST51: YES), the memory system 1 is set to a first write mode (ST12).

In a case where the count time is less than the threshold (ST51: NO), the memory system 1 is set to a second write mode (ST13).

Upon completion of the processing of ST12 or ST13, the memory controller 10a ends the series of operations shown in FIG. 17 (End).

Other operations of the memory system 1 according to the second embodiment are similar to those of the first embodiment.

### <2-3> Advantageous Effects of Second Embodiment

As described above, the write method of data may be changed based on the operating time of the memory system 1. Even in such a case, the memory system 1 according to the second embodiment can realize the PLP function within a device guarantee period and improve the reliability and performance of the device to the extent possible, similarly to the first embodiment.

### <3> Others

In the memory controller 10 in the above embodiments, a micro processing unit (MPU) may be used instead of the CPU 13. In addition, each of the processing described in the above embodiments can be executed by a dedicated hardware circuit, a processor that executes a program (firmware), or a combination thereof. In the present specification, “connection” indicates electrical connection, and does not exclude that another element is interposed therebetween.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A memory system, comprising:
a memory device configured to store data in a nonvolatile manner;
a memory controller configured to control the memory device;
a power supply circuit configured to generate power for driving the memory device and the memory controller based on power supplied from an external power supply, and supply the generated power to the memory device and the memory controller; and
a power storage device configured to be capable of storing electric energy and to supply the electric energy to the memory device and the memory controller through the power supply circuit in a case where power supply from the external power supply is stopped, wherein
the memory controller is further configured to apply one of a first write mode and a second write mode having different power consumption to a write operation for the memory device according to a power storage capacity of the power storage device.

2. The memory system according to claim 1, wherein
the memory device comprises a cell unit including a plurality of memory cells each capable of storing multi-bit data,
the memory controller is further configured to manage a storage area of the memory device in units of the cell units, the storage area including a first cell unit and a second cell unit which are continuous,
the write operation includes a first stage program and a second stage program for each of the cell units, and
the memory controller is further configured to execute the first stage program for the first cell unit, the first stage program for the second cell unit, and the second stage program for the first cell unit in a stated order in the write operation.

3. The memory system according to claim 2, wherein
the memory cell is configured to store N-bit data (N is an integer of 3 or more), and
the memory controller is further configured to:
execute a rough write operation of the N-bit data by the first stage program, and execute a fine write operation of the N-bit data by the second stage program in a case of the first write mode is applied to, and
execute a rough write operation of M-bit data (M is an integer of 1 or more and less than N) by the first stage program, and execute a fine write operation of the N-bit data by the second stage program in a case of the second write mode is applied to.

4. The memory system according to claim 3, wherein
the memory controller is further configured to select the first write mode in a case where the power storage capacity of the power storage device is equal to or greater than a threshold, and select the second write mode in a case where the power storage capacity of the power storage device is less than the threshold.

5. The memory system according to claim 3, wherein
the memory controller is further configured to, in the second stage program of the second write mode, read the data written in the first stage program to the selected cell unit before executing the fine write operation of the N-bit data to the selected cell unit, and use the read data in the fine write operation of the N-bit data.

6. The memory system according to claim 3, wherein
each of the first stage program and the second stage program includes an operation of applying a program voltage to a plurality of memory cells included in a selected cell unit a plurality of times while stepping up the program voltage, and
a step-up width of the program voltage in the rough write operation is larger than a step-up width of the program voltage in the fine write operation in the first and second stage programs.

7. The memory system according to claim 3, wherein
N is 4.

8. The memory system according to claim 1, wherein
the memory controller is further configured to periodically check the power storage capacity of the power storage device.

9. The memory system according to claim 1, wherein
the power storage device includes an electrolytic capacitor or an electric double layer capacitor.

10. The memory system according to claim 1, wherein
the memory controller is further configured to select the first write mode or the second write mode on a basis of an operating time of the memory system.

11. A method of controlling a memory system including a memory device configured to store data in a nonvolatile manner, a power supply circuit configured to generate power for driving the memory device based on power supplied from an external power supply and supply the generated power to the memory device, and a power storage device configured to be able to store electric energy, the method comprising:
supplying the electric energy from the power storage device to the memory device through the power supply circuit in a case where power supply from the external power supply is stopped; and
applying one of a first write mode and a second write mode having different power consumption to a write operation for the memory device according to a power storage capacity of the power storage device in a case where power is supplied from the external power supply.

12. The method according to claim 11, wherein
the memory device comprises a cell unit including a plurality of memory cells each capable of storing multi-bit data, a storage area of the memory device is managed in units of the cell units, the storage area includes a first cell unit and a second cell unit which are continuous, and the write operation includes a first stage program and a second stage program for each of the cell units, and
the method further comprising executing, in the write operation, the first stage program for the first cell unit, the first stage program for the second cell unit, and the second stage program for the first cell unit in a stated order.

13. The method according to claim 12, wherein
the memory cell is configured to store N-bit data (N is an integer of 3 or more), and
the method comprising:
executing a rough write operation of N-bit data by the first stage program and executing a fine write operation of the N-bit data by the second stage program in a case of the first write mode is applied to; and
executing a rough write operation of M-bit data (M is an integer of 1 or more and less than N) by the first stage program and executing a fine write operation of the N-bit data by the second stage program in a case of the second write mode is applied to.

14. The method according to claim 13, further comprising:
selecting the first write mode in a case where the power storage capacity of the power storage device is equal to or greater than a threshold, and selecting the second write mode in a case where the power storage capacity of the power storage device is less than the threshold.

15. The method according to claim 13, further comprising:
reading data written to a selected cell unit in the first stage program, and using the read data in the fine write operation of N-bit data before executing a fine write operation of N-bit data on the selected cell unit, in the second stage program of the second write mode.

16. The method according to claim 13, wherein
each of the first stage program and the second stage program includes an operation of applying a program voltage to a plurality of memory cells included in a selected cell unit a plurality of times while stepping up the program voltage, and
a step-up width of the program voltage in the rough write operation is larger than a step-up width of the program voltage in the fine write operation in the first and second stage programs.

17. The method according to claim 13, wherein
N is 4.

18. The method according to claim 11, further comprising:
periodically checking the power storage capacity of the power storage device.

19. The method according to claim 11, wherein
the power storage device includes an electrolytic capacitor or an electric double layer capacitor.

20. The method according to claim 11, further comprising:
selecting the first write mode or the second write mode on a basis of an operating time of the memory system.
